(19) United States
(12) Patent Application Publication
(10) Pub. No.: US 2023/0093870 A1
(43) Pub. Date: Mar. 30, 2023

(54) Method for Forming Resistance on Circuit Board and Circuit Board Having Resistance

(71) Applicant: Unimicron Technology Corporation, Taoyuan City 333 (TW)

(72) Inventors: Chin-Sheng Wang, Taoyuan City (TW); Kai-Ming Yang, Taoyuan City (TW); Chen-Hao Lin, Taoyuan City (TW)

(21) Appl. No.: 17/528,322

(22) Filed: Nov. 17, 2021

(30) Foreign Application Priority Data
Sep. 29, 2021 (TW) 110136299

(51) Int. Cl. H05K 3/04; H05K 3/46; H05K 1/02

(52) U.S. Cl. CPC H05K 3/048; H05K 3/467; H05K 1/0298

(57) ABSTRACT

A method for forming resistance on circuit board is provided and includes the following steps. First, a substrate is provided. Next, a second metal layer is provided on the substrate, and the first metal layer is covered by the second metal layer. Then, a resistance is formed on the second metal layer, and the resistance is directly above the first metal layer. Thereafter, the second metal layer is cut so that the edge of the second metal layer is aligned with that of the first metal layer. The second metal layer is separated from the first metal layer. Next, the second metal layer is pressed with a circuit board, and the resistance is attached to a dielectric layer of the circuit board. Then, the second metal layer is etched to form a circuit pattern on the resistance.

### FIELD OF THE DISCLOSURE

The present disclosure relates to a technical field of processing printed circuit boards, and more particularly to a method for forming resistance on circuit board and circuit board having the resistance.

### BACKGROUND OF THE INVENTION

Please refer to FIG. 1A and FIG. 1B. FIG. 1A illustrates a schematic view of a prototype 10 of a circuit board. FIG. 1B illustrates a schematic view of a circuit board 10P. Now, the prototype 10 for manufacturing a circuit board includes a metal layer 12, a whole piece of resistance material 13, and a dielectric layer 14. First off, the prototype 10 needs to be cut to an appropriate size. Next, two photolithography processes are required to etch the metal layer 12 and the resistance material 13, respectively, for manufacturing a circuit board 10P having a resistance 13′ (please refer to FIG. 1B). As a result, the cost for manufacturing the circuit board 10P is high.

In addition, the cutting and the photolithography processes cause waste and loss of the prototype 10 in manufacturing the circuit board. Besides, the prototype 10 is easy to be oxidized, so the prototype 10 has limited life span. Furthermore, in the future, due to increasing capabilities and shrinking sizes of electronic components, it is not easy to adjust the resistance values of the resistance by etching, resulting in the difficulty of manufacturing the circuit boards 10P having different resistance values. Moreover, the etching process will cause side etching, hard to meet the trend of electronic products becoming thinner and smaller.

Therefore, how to reduce the cost and the difficulty for manufacturing the circuit board having the resistance is worth considering for person having ordinary skill in the art.

### SUMMARY OF THE INVENTION

The objective of the present disclosure is providing a method for forming resistance on circuit board to reduce the manufacturing cost of the circuit board having the resistance and adjust the resistance value for different circuit boards by changing the thickness of the resistance, thereby reducing the difficulty for manufacturing the circuit board.

The method for forming resistance on circuit board includes following steps.
Step (a): A substrate is provided.
Step (b): A first metal layer is disposed on the substrate.
Step (c): A second metal layer covering the first metal layer is disposed on the substrate.
Step (d): A resistance is formed on the second metal layer, and the resistance is directly above the first metal layer.
Step (e): The second metal layer and the first metal layer are cut to remove the outer edges of the second metal layer and the first metal layer.
Step (f): The second metal layer is separated from the first metal layer.
Step (g): The second metal layer is pressed with a circuit board, and the resistance is attached to a dielectric layer of the circuit board.
Step (h): The second metal layer is etched to form a circuit pattern on the resistance.

In addition, the material of the first metal layer is different from the material of the second metal layer.

In the method for forming resistance on circuit board, the step (d) further includes following steps.
Step (d1): A photoresist layer is formed on the second metal layer.
Step (d2): A gap exposing the second metal layer is formed on the photoresist layer.
Step (d3): The resistance is formed in the gap.
Step (d4): The photoresist layer is removed.

In the method for forming resistance on circuit board, the resistance is formed in the gap via an electroplating method in the step (d3).

In the method for forming resistance on circuit board, the material of the resistance is nickel-phosphorus alloy or copper-nickel alloy.

In the method for forming resistance on circuit board, the material of the first metal layer is aluminum.

In the method for forming resistance on circuit board, the material of the second metal layer is copper.

In the method for forming resistance on circuit board, the substrate is a prepreg.

In the method for forming resistance on circuit board, the first metal layers are disposed on both sides of the substrate in the step (b), and the second metal layers are also disposed on both sides of the substrate in the step (c).

Another objective of the present disclosure is to provide a circuit board including a lower manufacturing cost and a lower manufacturing difficulty.

A circuit board in the present disclosure includes a dielectric layer, a resistance and a circuit pattern. The resistance is embedded in the dielectric layer. The circuit pattern is disposed on the upper surface of the dielectric layer.

In the circuit board, the circuit pattern is also disposed on the upper surface of the dielectric layer.

In the circuit board, the circuit board structure further includes a solder mask layer covering part of the circuit pattern.

In the circuit board, the material of the resistance is nickel-phosphorus alloy or copper-nickel alloy.

The present disclosure has the following advantages: reducing the manufacturing cost of the circuit board having the resistance and changing the thickness of the resistance within a limited range to adjust resistance values of the resistance.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A illustrates a schematic view of a prototype 10 of a circuit board;

FIG. 1B illustrates a schematic view of a circuit board 10P;

FIG. 2A illustrates a flow chart of a method for forming resistance on circuit board;

FIG. 2B illustrates a flow chart of sub-steps of a step S4;

FIG. 3A and FIG. 3M illustrate an embodiment of a manufacturing process of a circuit board 20; and

FIG. 3N illustrates a schematic view of a circuit pattern 22′ covered with a solder mask layer 28.

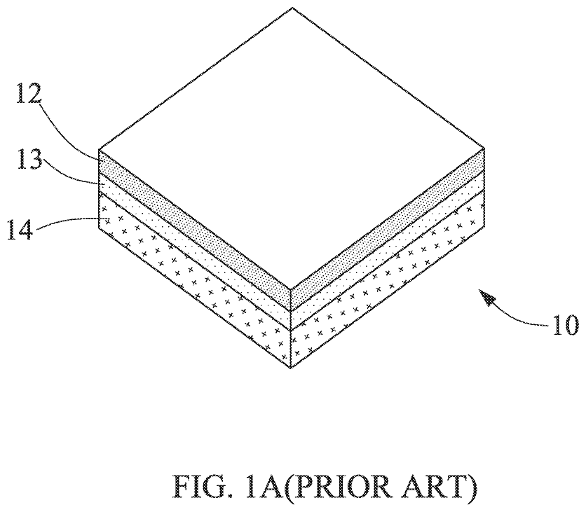

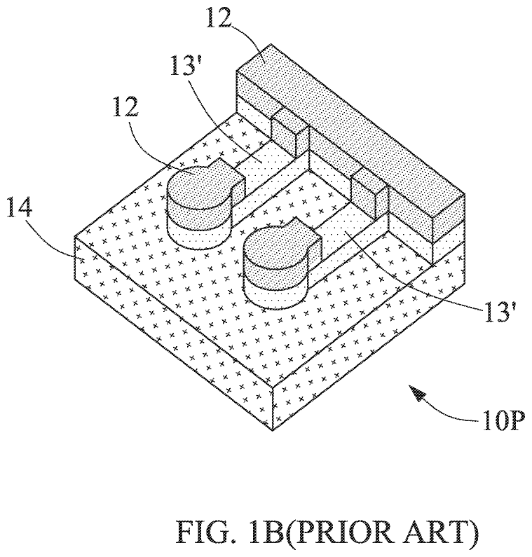

### DESCRIPTION OF THE PREFERRED EMBODIMENTS

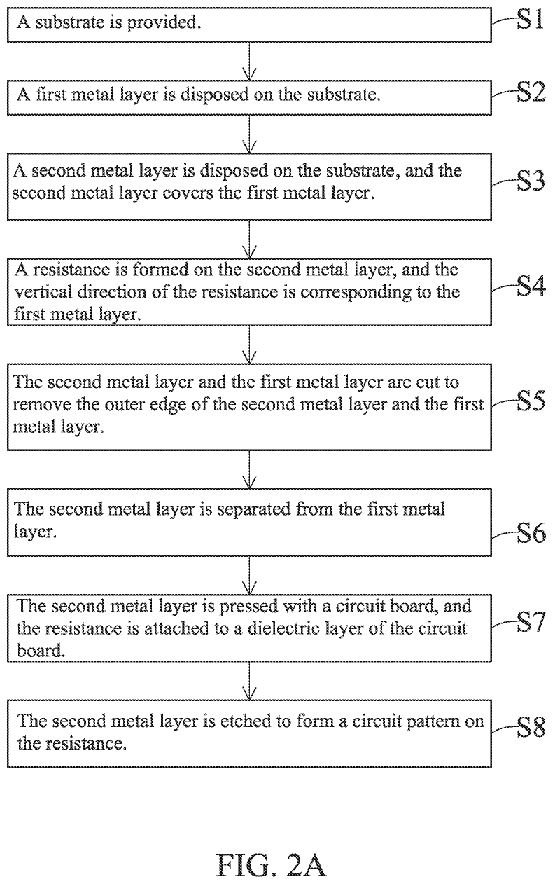

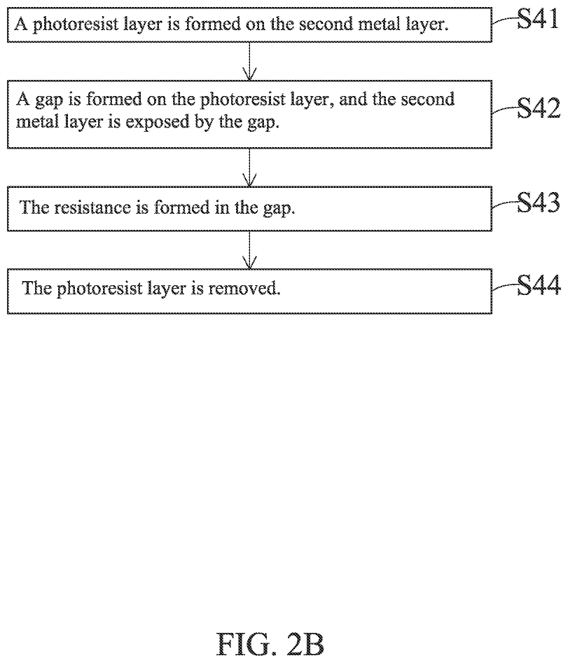

Please refer to FIG. 2A. FIG. 2A illustrates a flow chart of a method for forming resistance on circuit board. The method for forming resistance on circuit board in the present disclosure includes the following steps.

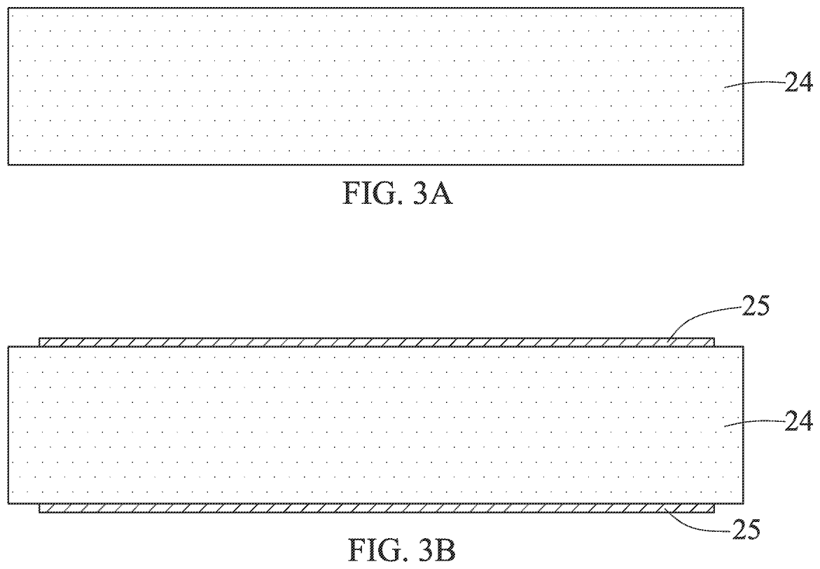

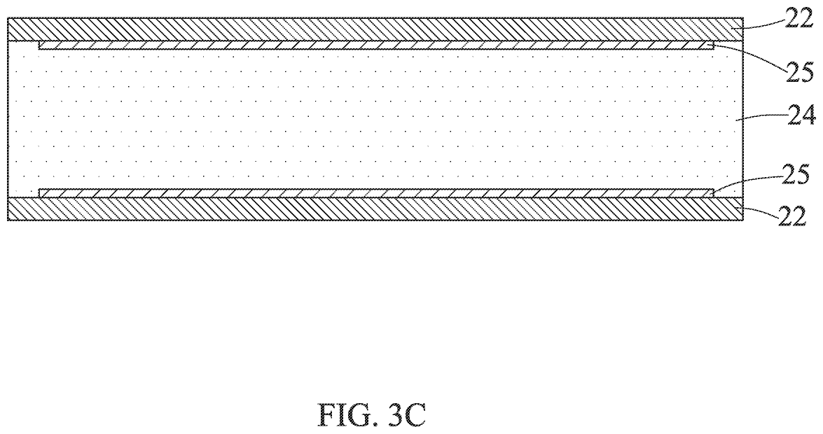

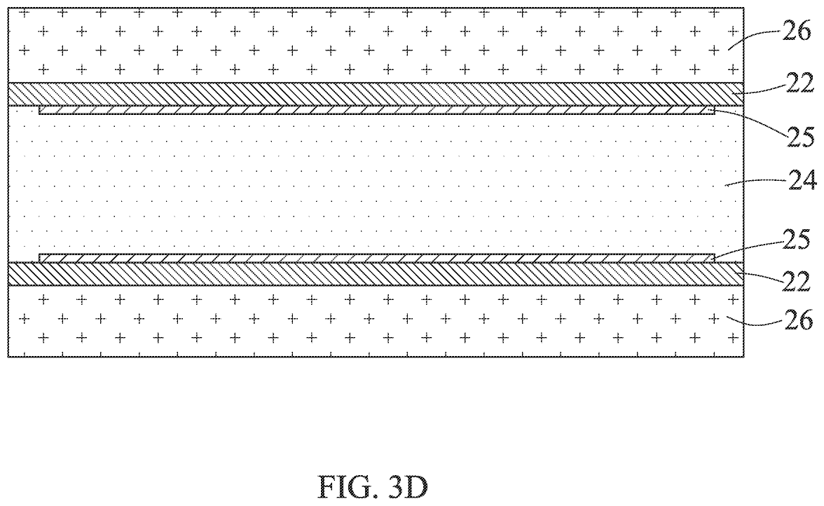

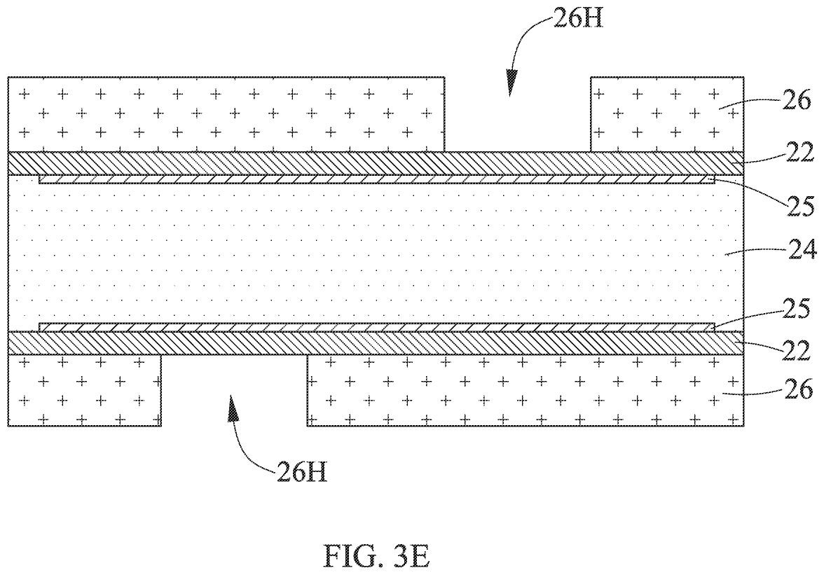

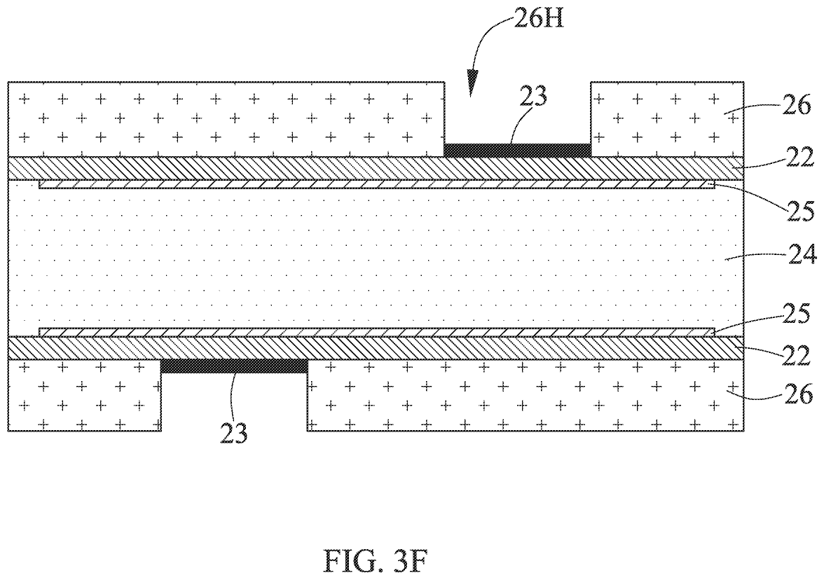

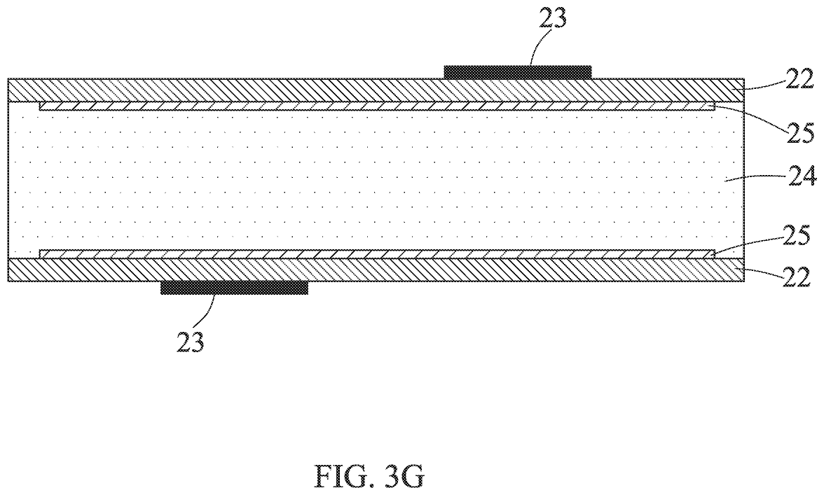

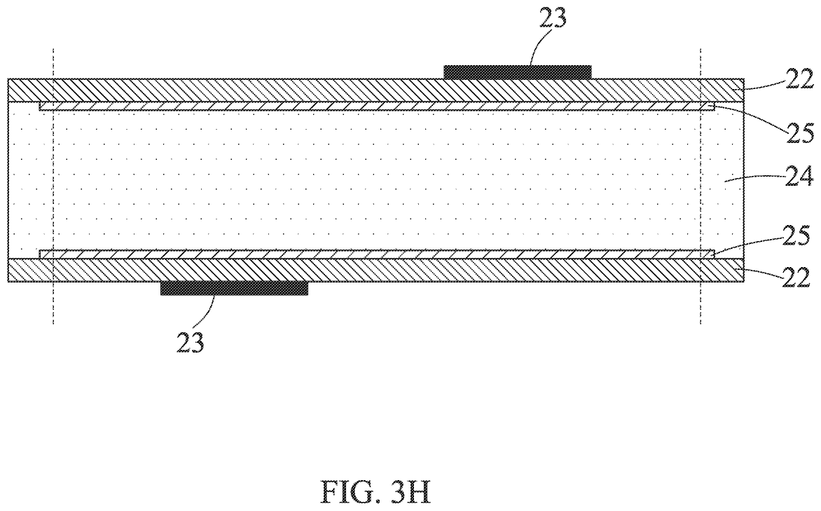

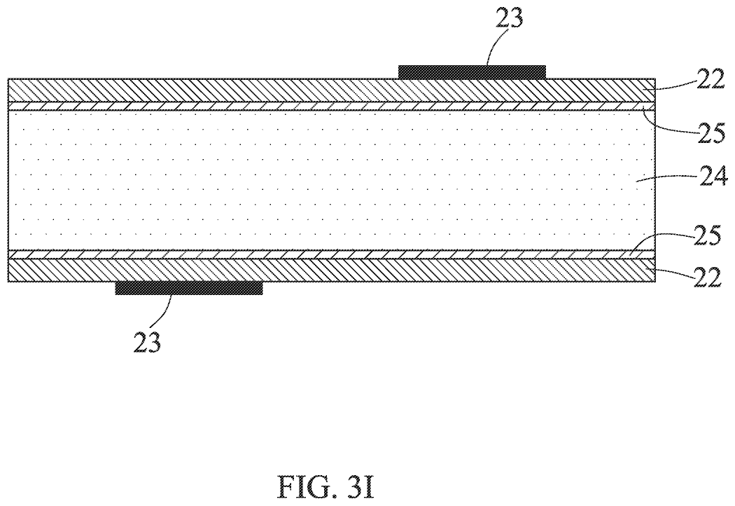

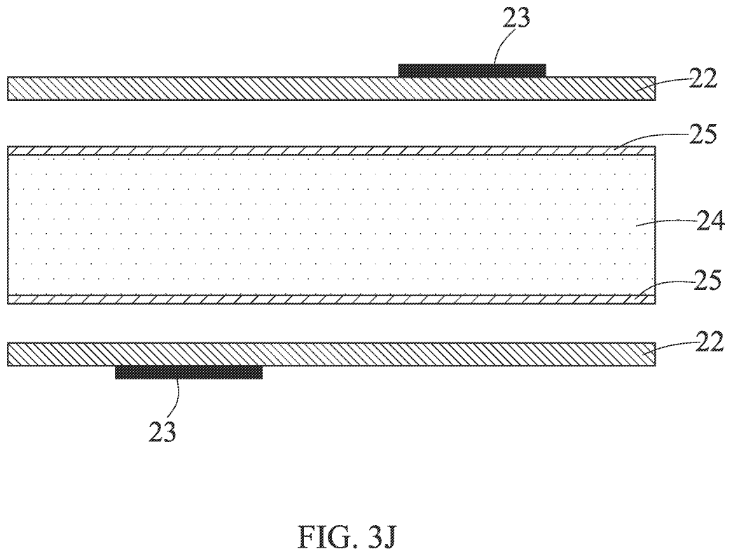

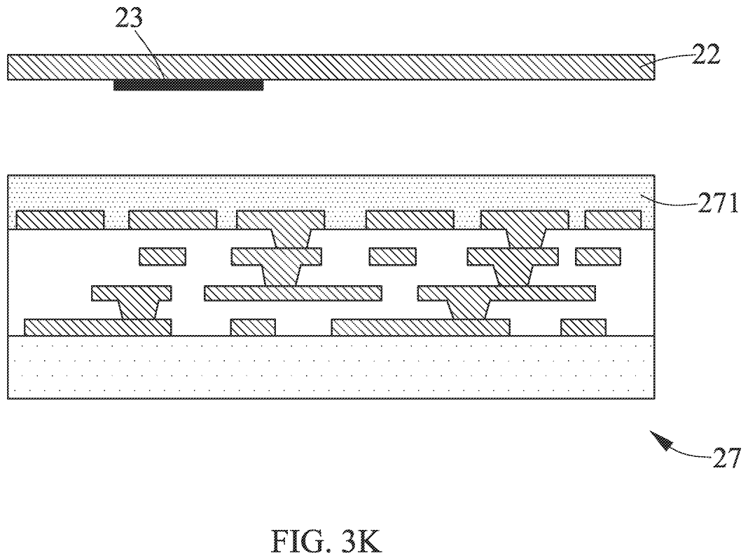

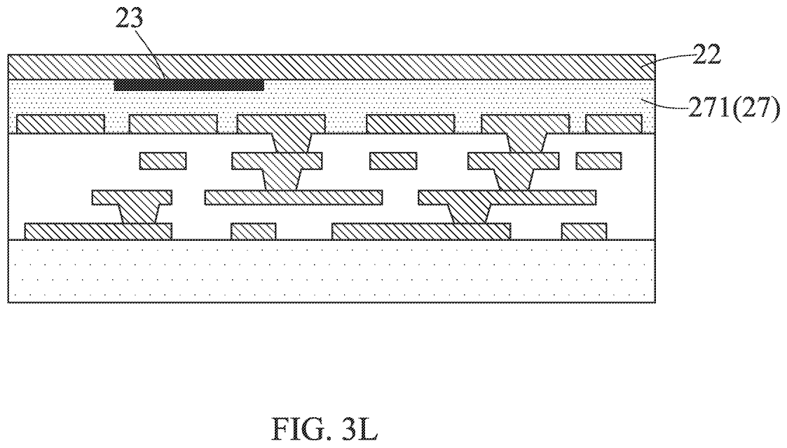

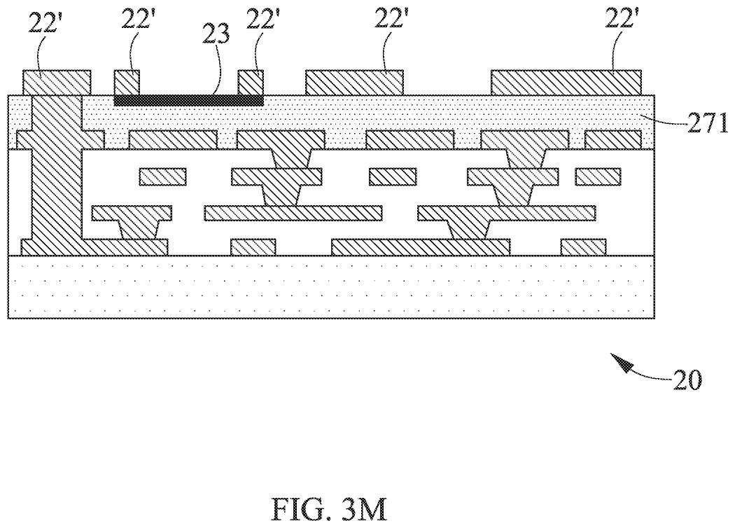

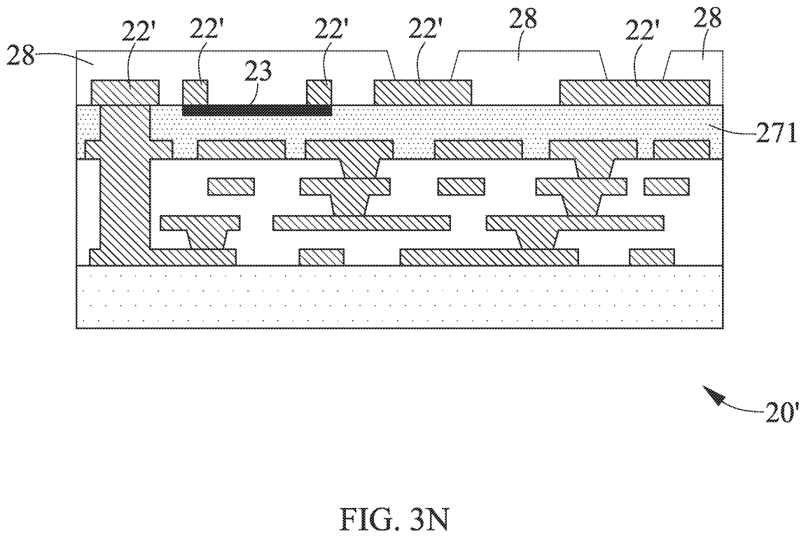

Please refer to the step S1 and FIG. 3A. A substrate 24 is provided. In the current embodiment, the substrate 24 is mainly made of a prepreg. In some embodiments, other materials are selected as the main material of the substrate 24 as long as the materials have the properties of high rigidity, sufficient chemical resistance, and non-conductivity. Next, please refer to the step S2 and FIG. 3B. First metal layers 25 are disposed on both sides of the substrate 24. The material of the first metal layer 25 is aluminum. In detail, a first metal layer 25 is first disposed on the surface of the substrate 24. Then, please refer to the step S3 and FIG. 3C. Second metal layers 22 are disposed on two both sides of the substrate 24. The material of the second metal layer 22 is copper. The first metal layer 25 is completely covered by the second metal layer 22. The second metal layer 22 and the first metal layer 25 are fixed on the substrate 24 by pressing. Therefore, the first metal layer 25 pressed by the second metal layer 22 is embedded in the substrate 24.

Please refer to the step S4. A resistance 23 is formed on the second metal layer 22. The material of the resistance 23 is nickel-phosphorus alloy or copper-nickel alloy. The resistance 23 is directly above the first metal layer 25. In other words, the resistance 23 is within the vertical extended boundary of the first metal layer 25. In the embodiment, the step S4 includes multiple steps (please refer to FIG. 2B). After these steps of the step S4 are performed completely, the resistance 23 is formed on the second metal layer 22. These steps of the step S4 are described as follows.

Please refer to the step S41 and FIG. 3D. A photoresist layer 26 is formed on the second metal layer 22. Next, please refer to the step S42 and FIG. 3E. A gap 26H for exposing the second metal layer 22 is formed on the photoresist layer 26. Then, please refer to the step S43 and FIG. 3F. The resistance 23 is formed in the gap 26H by an electroplating method. In this way, the resistance 23 is disposed on the second metal layer 22. Thereafter, please refer to the step S44 and FIG. 3G. The photoresist layer 26 is removed so that only the resistance 23 is remained on the second metal layer 22. Therefore, compared with the resistance made by etching in the prior art, the resistance 23 in the embodiment is generated by the electroplating method, and the resistances 23 having different resistance values are made by changing the thickness of the resistance 23. In addition, compared to the etching method, the method of generating the resistance via electroplating also reduces the waste and pollution from resistance materials. Furthermore, avoiding undercut in the formation of the resistance 23 in the embodiment is also an advantage compared with the prior art. Therefore, the resistance 23 is made with small volume and in line with the trend of electronic products becoming thinner and smaller.

Please refer to the step S5, FIG. 3H and FIG. 3I. The second metal layer 22, the first metal layer 25 and the substrate 24 are cut via a wheel cutter or other tools to remove the outer edges of the second metal layer 22 and the first metal layer 25. In the embodiment, after cutting, the lateral length of the second metal layer 22 is the same as the lateral length of the first metal layer 25. In other words, the edge of the second metal layer 22 is aligned with that of the first metal layer 25.

Please refer to the step S6 and FIG. 3J. The second metal layer 22 is separated from the first metal layer 25. More specifically, the material, e.g., copper, of the first metal layer 25 is different from the material, e.g., aluminum, of the second metal layer 22, so it is easy to separate the two metal layers by exerting a small but suitable force. Next, please refer to the step S7, FIG. 3K and FIG. 3L. The second metal layer 22 is pressed with a circuit board 27, and the resistance 23 is attached to a dielectric layer 271 of the circuit board 27. In particular, the second metal layer 22 is attached to the dielectric layer 271 of the circuit board 27 by pressing. The resistance 23 is sandwiched between the second metal layer 22 and the dielectric layer 271. Therefore, the resistance 23 by pressing is embedded in the dielectric layer 271.

Please refer to the step S8 and FIG. 3M. The second metal layer 22 is etched to form a circuit pattern 22′ on the resistance 23. In this way, the circuit board 20 in the embodiment is manufactured. Therefore, compared with the traditional manufacturing method, only one photolithography process to etch the metal layer is needed for manufacturing the circuit board 20 in the embodiment, and another photolithography process to etch the resistance material for forming the resistance like prior art is saved. Thus, the manufacturing cost of the circuit board 20 is kept down. In addition, because the resistance 23 in the embodiment is formed when it is needed, it is not an issue for keeping the resistance material.

Please refer to FIG. 3N. After the circuit board 20 is manufactured completely, a circuit pattern 22′ of the circuit board 20 is covered with a solder mask layer 28 to form a circuit board 20′. The solder mask layer 28 is adopted to prevent the circuit pattern 22′ from being directly exposed to the air.

Please refer to FIG. 3N. The circuit board 20′ in the embodiment includes a dielectric layer 271, a resistance 23, a circuit pattern 22′ and a solder mask layer 28. The resistance 23 is embedded in the dielectric layer 271, and the material of the resistance 23 is nickel-phosphorus alloy or copper-nickel alloy. In addition, the circuit pattern 22′ is disposed on the upper surface of the resistance 23 and the dielectric layer 271. Furthermore, the solder mask layer 28 covers part of the circuit pattern 22′. The circuit board 20′ is made by the method of forming resistance on the circuit board in the aforementioned embodiment, so the manufacturing cost of the circuit board 20′ is lower, and the manufacturing process of the circuit board 20′ is also not complicated. In summary, the method for forming resistance on circuit board in the present disclosure can reduce the manufacturing cost of the circuit board having the resistance and produce the circuit board having the resistance with different resistance value just by changing the thickness of the resistance, thereby reducing the manufacturing difficulty of the circuit board.

In the embodiment, the first metal layers 25 and the second metal layers 22 are disposed on both sides of the substrate 24, so the resistances 23 are also formed on both sides of the substrate 24. However, it is not necessary to dispose them on both sides in other embodiments. For example, the first metal layer 25 and the second metal layer 22 are disposed on only top side of the substrate 24.

Although the description above contains many specifics, these are merely provided to illustrate the invention and should not be construed as limitations of the invention's scope. Thus, it will be apparent to those skilled, in the art that various modifications and variations can be made in the system and processes of the present disclosure without departing from the spirit or scope of the invention.

1. A method for forming resistance on circuit board, comprising:
(a) providing a substrate;
(b) disposing a first metal layer on the substrate;
(c) disposing a second metal layer on the substrate, the second metal layer covering the first metal layer;
(d) forming a resistance on the second metal layer, the resistance being directly above the first metal layer;
(e) cutting the second metal layer and the first metal layer to remove the outer edges of the second metal layer and the first metal layer;
(f) separating the second metal layer from the first metal layer;
(g) pressing the second metal layer with a circuit board, the resistance attached to a dielectric layer of the circuit board; and
(h) etching the second metal layer to form a circuit pattern on the resistance;
wherein the material of the first metal layer is different from the material of the second metal layer.

2. The method for forming resistance on circuit board according to claim 1, wherein the step (d) further comprises multiple steps of:
(d1) forming a photoresist layer on the second metal layer;
(d2) forming a gap on the photoresist layer, the gap exposing the second metal layer;
(d3) forming the resistance in the gap; and
(d4) removing the photoresist layer.

3. The method for forming resistance on circuit board according to claim 2, wherein the resistance in the gap in the step (d3) is formed by an electroplating method.

4. The method for forming resistance on circuit board according to claim 1, wherein the material of the resistance is nickel-phosphorus alloy or copper-nickel alloy.

5. The method for forming resistance on circuit board according to claim 1, wherein the material of the first metal layer is aluminum.

6. The method for forming resistance on circuit board according to claim 1, wherein the material of the second metal layer is copper.

7. The method for forming resistance on circuit board according to claim 1, wherein the substrate is a prepreg.

8. The method for forming resistance on circuit board according to claim 1, wherein the first metal layers are disposed on both sides of the substrate in the step (b), and the second metal layers are also disposed on both sides of the substrate in the step (c).

9-12. (canceled)
